(19) United States
(12) Patent Application Publication
(10) Pub. No.: US 2020/0049841 A1
(43) Pub. Date: Feb. 13, 2020

(54) RADIATION DETECTOR AND RADIOGRAPHIC IMAGING APPARATUS

(71) Applicant: FUJIFILM CORPORATION, Tokyo (JP)

(72) Inventor: Munetaka KATO, Kanagawa (JP)

(21) Appl. No.: 16/505,711

(22) Filed: Jul. 9, 2019

(30) Foreign Application Priority Data
Aug. 8, 2018 (JP) 2018-149609

(51) Int. Cl. G01T 7/00; G01T 1/20; H05K 9/00

(52) U.S. Cl. CPC G01T 7/00; H05K 9/0079; G01T 1/20

(57) ABSTRACT

A radiation detector includes a substrate having a pixel region on a first surface of a flexible and resinous base material, a conversion layer that is provided in a partial region, including the pixel region, of the first surface and converts radiation into light, an electrical charge discharge layer that is provided on at least one surface of a surface, on the conversion layer side, in a laminate in which the substrate and the conversion layer are laminated, or a second surface opposite to the first surface of the base material, and the wiring line that is electrically connected to the electrical charge discharge layer, the base material has a through-hole provided in a region corresponding to a region other than the partial region, and the wiring line passes through the through-hole.

### CROSS-REFERENCE TO RELATED APPLICATION

This application claims priority from Japanese Patent Application No. 2018-149609, filed on Aug. 8, 2018, the disclosure of which is incorporated by reference herein in its entirety.

### BACKGROUND

### Field of the Invention

The present disclosure relates to a radiation detector and a radiographic imaging apparatus.

### Related Art

In the related art, radiographic imaging apparatuses that perform radiographic imaging for medical diagnosis have been known. A radiation detector for detecting radiation transmitted through a subject and generating a radiographic image is used for such radiographic imaging apparatuses.

As the radiation detector, there is one comprising a conversion layer, such as a scintillator, which converts radiation into light, and a substrate in which a plurality of pixels, which accumulate electrical charges generated depending on light converted in the conversion layer, are formed in a pixel region of a base material. In this type of radiation detector, in order to suppress influence of electromagnetic wave noise, static electricity, and the like from the outside, a technique of providing an antistatic layer and a conductive layer has been known. For example, in techniques described in JP2010-003849A and JP2012-112726A, the influence of the electromagnetic wave noise from the outside of the radiation detector is suppressed by providing the antistatic layer on the surface of the substrate opposite to a surface on which the conversion layer was provided. Additionally, for example, in the technique described in JP2006-258550A, the influence of the electromagnetic wave, static electricity, and the like noise from the outside of the radiation detector is suppressed by electrically connecting a conductive layer that covers the conversion layer, and a member having constant potential, which is provided on a back side of the substrate.

Meanwhile, it is known a flexible base material is known as the base material of the substrate of the radiation detector. By using the flexible substrate, for example, there is a case where the weight of the radiographic imaging apparatus (radiation detector) can be reduced and imaging of the subject becomes easy.

In the radiation detector using the flexible base material, electrical charges tend to be generated compared to a radiation detector using a non-flexible base material. Particularly, in a case where a base material thinner than a glass base material is used, the electrical charges tend to stay. There is a case where the electrical charges generated in this way are non-uniformly present, and there is a case where the quality of a generated radiographic image deteriorates such that unevenness occurs in the radiographic image. However, in the techniques described in JP2010-003849A, JP2012-112726A, and JP2006-258550A, there is a case where the electrical charges generated in the radiation detector using the flexible base material cannot be effectively discharged to the outside of the radiation detector.

### SUMMARY

An object of the present disclosure is to provide a radiation detector and a radiographic imaging apparatus capable of effectively discharging, to the outside, electrical charges that cause unevenness in a radiographic image, compared to a case where a wiring line for connecting an electrical charge discharge layer to a ground, such as a cassette housing, passes through the outside of a side of a substrate, even in a case where a flexible base material is used for the substrate.

In order to achieve the above object, a radiation detector of a first aspect of the present disclosure comprises a substrate having a pixel region where a plurality of pixels that accumulate electrical charges generated depending on light converted from radiation are formed on a first surface of a flexible and resinous base material; a conversion layer that is provided in a partial region, including the pixel region, of the first surface of the base material and converts the radiation into the light; an electrical charge discharge layer that is provided on at least one surface of a surface, on the conversion layer side, in a laminate in which the substrate and the conversion layer are laminated, or a second surface opposite to the first surface of the base material; and a wiring line that is electrically connected to the electrical charge discharge layer, the base material has a through-hole provided in a region corresponding to a region other than the partial region, and the wiring line passes through the through-hole.

In the radiation detector of a second aspect of the present disclosure based on the radiation detector of the first aspect, the electrical charge discharge layer is at least one of an antistatic layer or a conductive layer.

In the radiation detector of a third aspect of the present disclosure based on the radiation detector of the first aspect or second aspect, the electrical charge discharge layer is provided on the surface of the laminate on the conversion layer side, and has a higher stiffness than the base material.

In the radiation detector of a fourth aspect of the present disclosure based on the radiation detector of any one aspect of the first aspect to third aspect, the electrical charge discharge layer is provided on the surface of the laminate on the conversion layer side, and is thicker than the base material.

In the radiation detector of a fifth aspect of the present disclosure based on the radiation detector of the first aspect, the electrical charge discharge layer is an adhesive layer that is provided on the surface of the laminate on the conversion layer side, is electrically connected to the wiring line, and has conductivity, and the radiation detector further comprises a reinforcing substrate bonded to the laminate by the adhesive layer.

In the radiation detector of a sixth aspect of the present disclosure based on the radiation detector of the fifth aspect, the reinforcing substrate has a higher stiffness than the base material.

In the radiation detector of a seventh aspect of the present disclosure based on the radiation detector of the fifth aspect or sixth aspect, the reinforcing substrate is provided on the surface of the laminate on the conversion layer side and is thicker than the base material.

In the radiation detector of an eighth aspect of the present disclosure based on any one aspect of the first aspect to seventh aspect, the wiring line passes through the electrical charge discharge layer.

The radiation detector of a ninth aspect of the present disclosure based on any one aspect of the first aspect to eighth aspect further comprises a protective layer that is provided on the first surface of the base material and covers the conversion layer, and the through-hole provided in the base material is provided outside a region where the protective layer is provided.

In the radiation detector of a tenth aspect of the present disclosure based on any one aspect of the first aspect to ninth aspect, the base material is provided with a plurality of the through-holes.

A radiographic imaging apparatus of an eleventh aspect of the present disclosure comprises the radiation detector according to any one aspect of the first aspect to the tenth aspect; a driving unit that is electrically connected to one side of the substrate and causes electrical charges to be read from the plurality of pixels depending on a control signal; and a signal processing unit that is electrically connected to a side different from the one side of the substrate, receives electrical signals according to the electrical charges read from the plurality of pixels, and generates image data according to the input electrical signals.

In the radiographic imaging apparatus of a twelfth aspect of the present disclosure based on the radiographic imaging apparatus of the eleventh aspect, the through-hole provided in the base material is provided at a side of the base material different from the sides to which the driving unit and the signal processing unit are connected.

The radiographic imaging apparatus of a thirteen aspect of the present disclosure based on the radiographic imaging apparatus of the eleventh aspect or twelfth aspect further comprises a housing that houses the radiation detector, the driving unit, and the signal processing unit, and the wiring line is electrically connected to the housing.

According to the present disclosure, it is possible to effectively discharge, to the outside, the electrical charges that cause unevenness in a radiographic image, compared to a case where the wiring line for connecting the electrical charge discharge layer to a ground, such as a cassette housing, passes through the outside of a side of the substrate, even in a case where the flexible base material is used for the substrate.

### BRIEF DESCRIPTION OF THE DRAWINGS

FIG. 1 is a block diagram illustrating an example of the main-parts configuration of the electrical system in the radiographic imaging apparatus of a first embodiment.

FIG. 2 is the plan view seen from the side by that an example of the radiation detector of a first embodiment was provided in the conversion layer.

FIG. 3 is an A-A line sectional view of the radiation detector illustrated in FIG. 3.

FIG. 4 is a sectional view for explaining the peripheral edge part and the central part in a conversion layer of the first embodiment.

FIG. 5 is the plan view seen from the side by that the radiographic imaging apparatus for explaining an example of the position in that the through-hole (wiring line) in the sensor substrate of a first embodiment was provided was provided in the conversion layer.

FIG. 6 is a sectional view for explaining an example of the producing method of the radiation detector of a first embodiment.

FIG. 7 is a section for explaining the flow of discharge of the electrical charges in the radiation detector of a first embodiment.

FIG. 8 is a sectional view of an example of a radiation detector of a second embodiment.

FIG. 9 is a sectional view of other examples of the radiation detector of a second embodiment.

FIG. 10 is the plan view seen from the side by that an example of a radiation detector of a third embodiment was provided in the conversion layer.

FIG. 11 is an A-A line sectional view of the radiation detector illustrated in FIG. 10.

FIG. 12 is a section for explaining the flow of discharge of the electrical charges in the radiation detector of a third embodiment.

FIG. 13 is a sectional view showing the section of other examples of the radiation detector of a third embodiment.

FIG. 14 is a sectional view showing the section of other examples of the electrical charge discharge layer in the radiation detector of an embodiment.

FIG. 15 is a sectional view showing the section of other examples of the electrical charge discharge layer in the radiation detector of an embodiment.

FIG. 16 is a sectional view showing the section of other examples of the radiation detector of an embodiment.

FIG. 17 is a sectional view showing the section of other examples of the radiation detector of a third embodiment.

FIG. 18 is the plan view seen from the side by that the radiographic imaging apparatus for explaining other examples of the position in that the through-hole (wiring line) in the sensor substrate of an embodiment was provided was provided in the conversion layer.

FIG. 19 is a sectional view showing the section of an example of the radiographic imaging apparatus that applied the radiation detector of the embodiment.

FIG. 20 is a sectional view showing the section of other examples of the radiographic imaging apparatus that applied the radiation detector of the embodiment.

### DETAILED DESCRIPTION

Hereinafter, embodiments of the invention will be described in detail with reference to the drawings. In addition, the present embodiments do not limit the invention.

### First Embodiment

A radiographic imaging apparatus of the present embodiment has a function of capturing a radiographic image of an object to be imaged, by detecting radiation transmitted through a subject, which is the object to be imaged, and outputting image information representing a radiographic image of the subject.

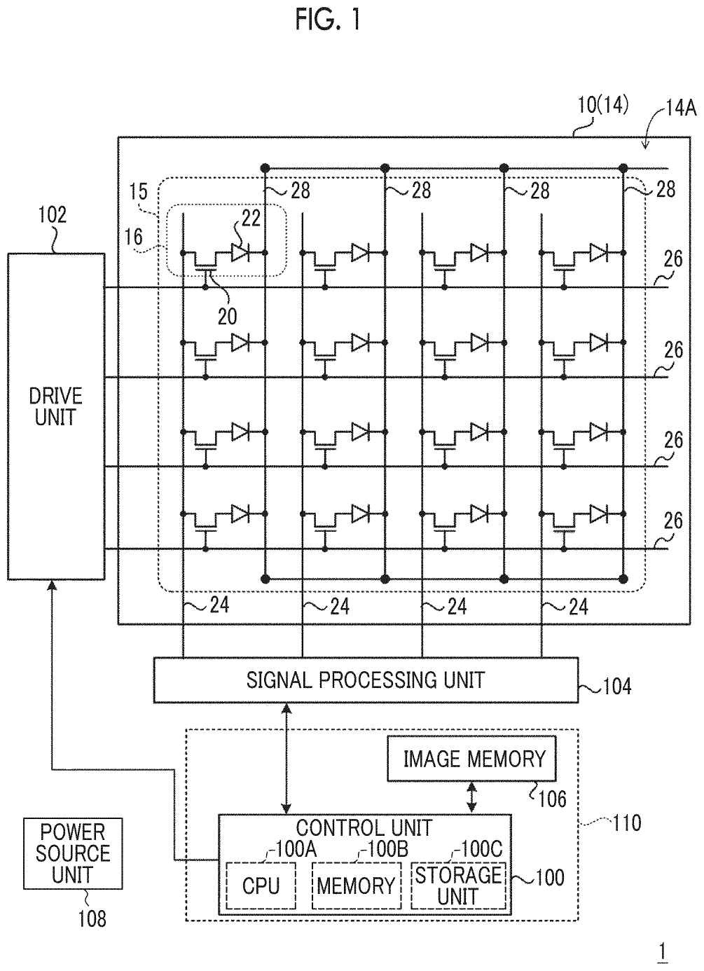

First, the outline of an example of the configuration of an electrical system in the radiographic imaging apparatus of the present embodiment will be described with reference to FIG. 1. FIG. 1 is a block diagram illustrating an example of the configuration of main parts of the electrical system in the radiographic imaging apparatus of the present embodiment.

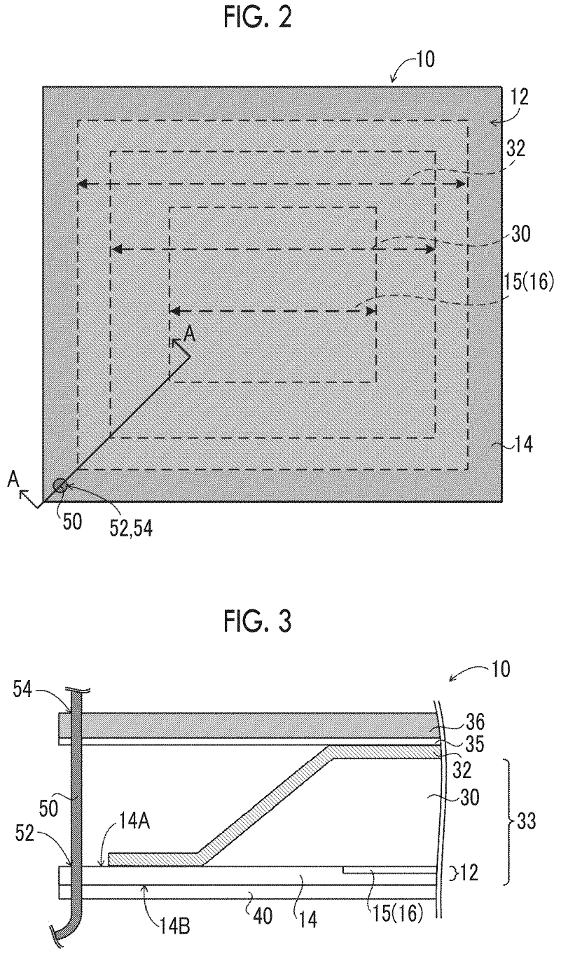

A radiation detector 10 comprises a sensor substrate 12 (refer to FIGS. 2 and 3) and a conversion layer 30 (refer to FIGS. 2 and 3) that converts radiation into light. The sensor substrate 12 comprises a flexible base material 14 to be described in detail, and a plurality of pixels 16 provided on a first surface 14A of the base material 14. In addition, in the following, the plurality of pixels 16 may be simply referred to as “pixels 16”. The sensor substrate 12 of the present embodiment is an example of a substrate of the present disclosure.

As illustrated in FIG. 1, each pixel 16 of the present embodiment includes a sensor part 22 that generates and accumulates electrical charges depending on the light converted by the conversion layer, and a switching element 20 that reads the electrical charges accumulated in the sensor part 22. In the present embodiment, as an example, a thin film transistor (TFT) is used as the switching element 20. For that reason, in the following description, the switching element 20 is referred to as a “TFT20”.

The pixels 16 are two-dimensionally arranged in one direction (a scanning wiring direction corresponding to a transverse direction of FIG. 1, hereinafter referred to as a “row direction”), and a direction intersecting the row direction (a signal wiring direction corresponding to the longitudinal direction of FIG. 1, hereinafter referred as a “column direction”) in a pixel region 15 of the sensor substrate 12. Although an array of the pixels 16 is illustrated in a simplified manner in FIG. 1, for example, 1024×1024 pixels 16 are arranged in the row direction and the column direction.

Additionally, a plurality of scanning wiring lines 26, which are provided for respective rows of the pixels 16 to control switching states (ON and OFF) of the TFTs 20, and a plurality of signal wiring lines 24, which are provided for respective columns of the pixels 16 and from which electrical charges accumulated in the sensor parts 22 are read, are provided in a mutually intersecting manner in the radiation detector 10. The plurality of scanning wiring lines 26 are electrically connected to a driving unit 102, respectively. The control unit 100 to be described below is connected to the driving unit 102 which outputs driving signals depending on a control signal output from the control unit 100. Driving signals, which are output from the driving unit 102 to drive the TFTs 20 to control the switching states thereof, flow to the plurality of scanning wiring lines 26, respectively. Additionally, the plurality of signal wiring lines 24 are electrically connected to the signal processing unit 104, respectively, and thereby, electrical charges read from the respective pixels 16 are output to the signal processing unit 104 as electrical signals. The signal processing unit 104 generates and outputs image data according to the input electrical signals.

The control unit 100 to be described below is connected to the signal processing unit 104, and the image data output from the signal processing unit 104 is sequentially output to the control unit 100. The image memory 106 is connected to the control unit 100, and the image data sequentially output from the signal processing unit 104 is sequentially stored in the image memory 106 under the control of the control unit 100. The image memory 106 has a storage capacity capable of storing image data equivalent to a predetermined number of sheets, and whenever radiographic images are captured, image data obtained by the capturing is sequentially stored in the image memory 106.

The control unit 100 includes a central processing unit (CPU) 100A, a memory 100B including a read only memory (ROM), a random access memory (RAM), and the like, and a nonvolatile storage unit 100C, such as a flash memory. An example of the control unit 100 is a microcomputer or the like. The control unit 100 controls the overall operation of the radiographic imaging apparatus 1.

In addition, in the radiographic imaging apparatus 1 of the present embodiment, the image memory 106, the control unit 100, and the like are formed in the control substrate 110.

Additionally, common wiring lines 28 are provided in a wiring direction of the signal wiring lines 24 at the sensor parts 22 of the respective pixels 16 in order to apply bias voltages to the respective pixels 16. Bias voltages are applied to the respective pixels 16 from a bias power source by electrically connecting the common wiring lines 28 to the bias power source (not illustrated) outside the sensor substrate 12.

The power source unit 108 supplies electrical power to various elements and various circuits, such as the control unit 100, the driving unit 102, the signal processing unit 104, the image memory 106, and the power source unit 108. In addition, in FIG. 1, illustration of wiring lines, which connect the power source unit 108 and various elements or various circuits together, is omitted in order to avoid complication.

Moreover, the radiation detector 10 of the present embodiment will be described in detail with reference to FIGS. 2 and 3. FIG. 2 is a plan view of the radiation detector 10 of the present embodiment as seen from the side on which the conversion layer 30 is formed. Additionally, FIG. 3 is a cross-sectional view taken along line A-A of the radiation detector 10 in FIG. 2.

As illustrated in FIGS. 2 and 3, the radiation detector 10 of the present embodiment comprises the sensor substrate 12, the conversion layer 30, a protective layer 32, an adhesive layer 35, a reinforcing substrate 36, an antistatic layer 40, and s wiring line 50. As illustrated in FIG. 3, the antistatic layer 40, the sensor substrate 12, the conversion layer 30, the protective layer 32, the adhesive layer 35, and the reinforcing substrate 36 are laminated in this order. In addition, in the following description, the term “on” in the structure of the radiation detector 10 means “on” in a positional relationship with reference to the sensor substrate 12 side. The adhesive layer 35 and the antistatic layer 40 of the present embodiment are an example of the electrical charge discharge layer of the present disclosure, and the adhesive layer 35 is an example of a conductive layer of the present disclosure.

The base material 14 is made of resin and has flexibility. The base material 14 is, for example, a resin sheet including plastics, such as polyimide. The thickness of the base material 14 may be a thickness such that desired flexibility is obtained depending on the hardness of a material, the size of the sensor substrate 12, and the like. For example, in a case where the base material 14 may be the resin sheet, the thickness thereof is 5 μm to 125 μm, and the thickness thereof may be more preferably 20 μm to 50 μm.

In addition, the base material 14 has characteristics capable of withstanding the manufacture of the pixels 16, and has characteristics capable of withstanding the manufacture of amorphous silicon TFT (a-Si TFT) in the present embodiment. As such characteristics of the base material 14, it is preferable that the coefficient of thermal expansion at 300° C. to 400° C. is comparable (for example, ±5 ppm/K) with a silicon (Si) wafer, and specifically, it is preferable that the coefficient of thermal expansion is 20 ppm/K or less. Additionally, as the coefficient of thermal contraction of the base material 14, it is preferable that the coefficient of thermal contraction in a machine direction (MD) at 400° C. is 0.5% or less in a state where the thickness is 25 μm. Additionally, it is preferable that the elastic modulus of the base material 14 does not have a transition point that general polyimide has, in a temperature region of 300° C. to 400° C., and the elastic modulus at 500° C. is 1 GPa or more. A specific example of the resin sheet having such characteristics is XENOMAX (registered trademark).

In addition, as a method of measuring the above thickness, coefficient of thermal expansion, elastic modulus, and mean particle diameter, and the like in the present embodiment, an evaluation method described in the JP2010-76438A is applied. For example, in a method of measuring the coefficient of thermal expansion, expansion and contraction ratios in the MD and in a transverse direction (TD) were measured on the following conditions, the expansion and contraction ratios and temperatures at intervals of 10° C. including 90° C. to 100° C., 100° C. to 110° C., and . . . , were measured, the measurement was performed up to 400° C., and the coefficient of thermal expansion (ppm/° C.) derived as an average value of all measurement values from 100° C. to 350° C. was converted into (ppm/K). As the measurement conditions of the coefficient of thermal expansion, a TMA4000S device made by MAC science Co., Ltd. is used, sample length is 10 mm, sample width is 2 mm, initial load is 34.5 g/mm², temperature increase start temperature is 25° C., temperature increase end temperature is 400° C., temperature increase rate is 5° C./min, and atmosphere is in argon.

As illustrated in FIGS. 2 and 3, the conversion layer 30 of the present embodiment is provided on a partial region, including the pixel region 14, of the sensor substrate 12 provided on the first surface 14A of the base material 15 of the sensor substrate 12. In this way, the conversion layer 30 of the present embodiment is not provided on a region of an outer peripheral part of the first surface 14A of the base material 14.

In this way, the conversion layer 30 covers the pixel region 15. In the present embodiment, a scintillator including CsI (cesium iodide) is used as an example of the conversion layer 30. It is preferable that such a scintillator includes, for example, CsI:Tl (cesium iodide to which thallium is added) or CsI:Na (cesium iodide to which sodium is added) having an emission spectrum of 400 nm to 700 nm at the time of X-ray radiation. In addition, the emission peak wavelength in a visible light region of CsI:Tl is 565 nm.

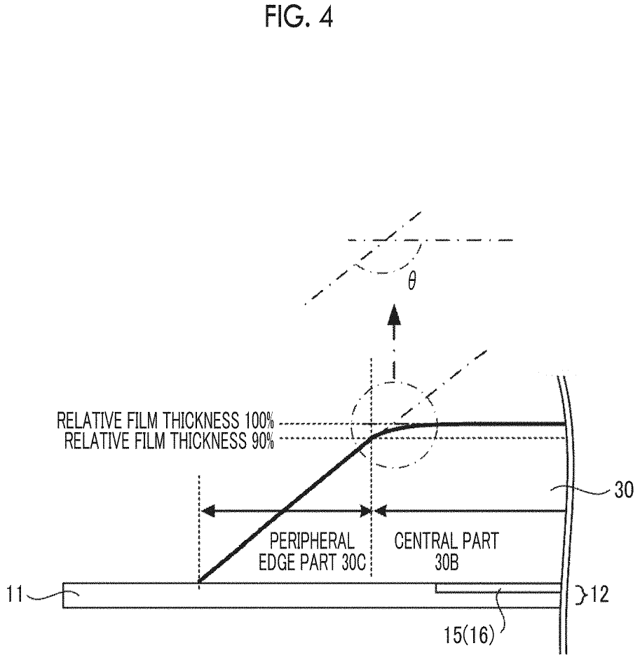

As illustrated in FIG. 4, as a specific example, in the conversion layer 30 of the present embodiment, the thickness of a region at an outer periphery thereof tends to decrease toward the outside as viewed as a whole. For this reason, the region at the outer periphery has an inclination such that the thickness thereof decreases toward the outside. In the present embodiment, an average value of thicknesses of the conversion layer 30, which are regarded as being substantially constant in a case where a manufacturing error and a measurement error is neglected and are within a predetermined range from the center of the conversion layer 30, is adopted as a reference, and as illustrated in FIG. 4, as an example, an outer peripheral region where a relative film thickness (hereinafter referred to as “relative film thickness”) to a reference thickness is 90% or less is referred to as a “peripheral edge part (peripheral edge part 30C)”. Additionally, the region of the conversion layer 30 surrounded by the peripheral edge part 30C is referred to as a “central part (central part 30B)”. In other words, the “central part” means a region that includes at least a portion in which the thickness of the conversion layer 30 is substantially constant and that also includes a portion in which the relative film thickness exceeds 90%. In addition, in the present embodiment, as illustrated in FIGS. 3 and 4, the pixel region 15 is smaller than the central part 30B, and the pixel region 15 is covered with the central part 30B.

As a specific example, in the present embodiment, an outer peripheral region, which is within a region of less than 5 mm from the outer periphery of the conversion layer 30 and has a relative film thickness of 90% or less, is referred to as a “peripheral edge part (peripheral edge part 30C)”. For that reason, as illustrated in FIG. 3, FIG. 4, and the like, in the peripheral edge part 30C, the thickness of the conversion layer 30 tends to gradually decrease toward the outer periphery (edge).

In addition, in the present embodiment, a form in which the inclination angle has a constant inclination of θ and the thickness decreases gradually has been exemplified as an example in which the thickness of the conversion layer 30 decreases toward an outer periphery. However, the invention is not limited to this form. For example, a form in which the thickness varies in a step-like shape.

In addition, the method of measuring the inclination angle θ is not particularly limited. However, in the present embodiment, as an example, in the method of measuring the inclination angle θ, portions of an end part of the conversion layer 30 were peeled from the sensor substrate 12 at the positions of four spots with regular intervals at one side of a rectangular conversion layer 30 and were obtained as respective samples. Measurement was performed by observing the four samples using an optical microscope after the four samples were polished and sectioned. An average value of measurement values of the four samples was set as the inclination angle θ at the side of the conversion layer 30 where the samples were prepared.

In the present embodiment, the conversion layer 30 of CsI is directly formed as a columnar crystal on the sensor substrate 12 by gaseous phase deposition methods, such as a vacuum vapor deposition method, a sputtering method, and a chemical vapor deposition (CVD) method. In this case, the side of the conversion layer 30, which is in contact with the pixels 16, becomes a base point side in a growth direction of the columnar crystal.

In addition, in this way, in a case where the conversion layer of CsI is directly formed by the gaseous phase deposition methods on the sensor substrate 12, for example, a reflective layer (not illustrated) having a function of reflecting the light converted in the conversion layer 30 may be provided on a surface opposite to a side that is in contact with the sensor substrate 12. The reflective layer may be directly provided on the conversion layer 30, and or may be provided via a pressure sensitive adhesive layer or the like. As a material of the reflective layer in this case, it is preferable to use an organic material, and it is preferable to use, for example, at least one of white polyethylene terephthalate (PET), TiO₂(Titanium oxide), Al₂O₃(Aluminum oxide), foamed white PET, a polyester-based high-reflection sheet, specular reflection aluminum, or the like. Particularly, it is preferable to use the white PET as the material from a viewpoint of reflectivity.

In addition, the white PET is obtained by adding a white pigment, such as TiO₂ or barium sulfate, to PET. Additionally, the polyester-based high-reflection sheet is a sheet (film) having a multilayer structure in which a plurality of thin polyester sheets are laminated. Additionally, the foamed white PET is white PET of which the surface is porous.

Additionally, in a case where the scintillator of CsI is used as the conversion layer 30, the conversion layer 30 can also be formed in the sensor substrate 12 by a method different from the method of the present embodiment. For example, the conversion layer 30 may be formed in the sensor substrate 12 by preparing CsI vapor-deposited on an aluminum sheet or the like by the vapor deposition method, and bonding the side of CsI, which is not in contact with the aluminum sheet, and the pixels 16 of the sensor substrate 12 with a pressure sensitive adhesive sheet or the like.

Moreover, unlike the radiation detector 10 of the present embodiment, GOS (Gadolinium oxysulfide doped with terbium (Gd₂O₂S:Tb)) or the like may be used as the conversion layer 30 instead of CsI. In this case, for example, a sheet bonded to a support formed of the white PET or the like with a pressure sensitive adhesive sheet or the like is prepared as a sheet in which GOS is dispersed in a binder, such as resin. The conversion layer 30 can be formed in the sensor substrate 12 by bonding the side of GOS on which the support is not bonded, and the pixels 16 of the sensor substrate 12 with a pressure sensitive adhesive sheet or the like.

Additionally, as illustrated in FIGS. 2 and 3, the protective layer 32 of the present embodiment is provided on the first surface 14A of the base material 14 of the sensor substrate 12, and covers the conversion layer 30 on the sensor substrate 12. The protective layer 32 of the present embodiment has a function of protecting the conversion layer 30 from moisture, such as humidity. Materials of the protective layer 32 include, for example, an organic film, and specifically, a single layer film or a laminated film made of PET, polyphenylene sulfide (PPS), oriented polypropylene (OPP), polyethylene naphthalate (PEN), polyimide (PI), and the like. Additionally, as the protective layer 32, an ALPET (registered trademark) sheet obtained by laminating aluminum, such as by bonding aluminum foil, on an insulating sheet (film), such as a parylene (registered trademark) film and PET, may be used.

Moreover, as illustrated in FIGS. 2 and 3, in the radiation detector 10 of the present embodiment, the adhesive layer 35 and the reinforcing substrate 36 are provided on a surface, on the conversion layer 30 side, in a laminate 33 in which the sensor substrate 12 and the conversion layer 30 are laminated. Specifically, as illustrated in FIG. 3, the adhesive layer 35 and the reinforcing substrate 36 are laminated on the conversion layer 30 via the protective layer 32. The reinforcing substrate 36 of the present embodiment is fixed to the protective layer 32 in a central part 30B (refer to FIG. 4) of the conversion layer 30 by the adhesive layer 35. In addition, in a case where the reinforcing substrate 36 is simply pressed against and fixed to the protective layer 32, there is a case where unnecessary electrical charges are generated at an interface due to the friction between the reinforcing substrate 36 and the protective layer 32 depending on the occurrence of shock or the like. Therefore, as in the radiation detector 10 of the present embodiment, the reinforcing substrate 36 is preferably fixed to the protective layer 32 by the adhesive layer 35 or the like.

The reinforcing substrate 36 is higher in stiffness than the base material 14, and the dimensional change (deformation) thereof with respect to a force applied in a direction perpendicular to the surface opposite to the first surface 14A is smaller than the dimensional change (deformation) thereof with respect to a force applied in the direction perpendicular to the first surface 14A of the base material 14. Additionally, the thickness of the reinforcing substrate 36 of the present embodiment is larger than the thickness of the base material 14. In this way, by making the stiffness of the reinforcing substrate 36 higher than that of the base material 14, the base material 14 (sensor substrate 12) can be made it difficult to deflect in the radiation detector 10. Additionally, by making the thickness of the reinforcing substrate 36 larger than the thickness of the base material 14, the base material 14 (sensor substrate 12) can be made it difficult to deflect in the radiation detector 10.

Additionally, as illustrated in FIGS. 2 and 3, the adhesive layer 35 and the reinforcing substrate 36 of the present embodiment are provided in a region wider than a region, where the conversion layer 30 and the protective layer 32 are provided, on the first surface 14A of the base material 14. For that reason, as illustrated in FIGS. 2 and 3, end parts of the adhesive layer 35 and the reinforcing substrate 36 protrude to the outside (the outer peripheral part side of the sensor substrate 12) of an outer peripheral part of the conversion layer 30.

The reinforcing substrate 36 is an insulating layer made of plastics. The plastics used as the material of the reinforcing substrate 36 are preferably thermoplastic resin, and include a least one of polycarbonate (PC), polyethylene terephthalate (PET), styrene, acrylics, polyacetase, nylon, polypropylene, acrylonitrile butadiene styrene (ABS), engineering plastics, polyethylene terephthalate, or polyphenylene ether. In addition, the reinforcing substrate 36 is preferably at least one of polypropylene, ABS, engineering plastics, polyethylene terephthalate or polyphenylene ether among these, is more preferably at least one of styrene, acrylics, polyacetase, or nylon, and is more preferably at least one of polycarbonate or polyethylene terephthalate.

Meanwhile, the adhesive layer 35 has conductivity, and has a function of fixing the reinforcing substrate 36 to the laminate 33. The materials of the adhesive layer 35 include an acrylic pressure sensitive adhesive, a hot-melt pressure sensitive adhesive, a silicone-based adhesive, and the like. Examples of the acrylic adhesive include urethane acrylate, acrylic resin acrylate, epoxy acrylate, and the like. Examples of the hot-melt pressure sensitive adhesive include thermoplastics, such as ethylene-vinyl acetate copolymer resin (EVA), ethylene-acrylate copolymer resin (EAA), ethylene-ethyl acrylate copolymer resin (EEA), and ethylene-methyl methacrylate copolymer (EMMA). The conductively of the adhesive layer 35 of the present embodiment is obtained by mixing conductive substances with these materials. Examples of the conductive substances to be mixed include, powders of metals, such as Cu (copper) and Al (aluminum), conductive polymer materials, such as polyacethylenes, and conductive materials, such as carbon, and mixtures thereof.

Meanwhile, the antistatic layer 40 is provided on the second surface 14B opposite to the first surface 14A of the base material 14 of the sensor substrate 12. In other words, the antistatic layer 40 is provided on the surface of the sensor substrate 12 opposite to the surface on which the conversion layer 30 is provided. As the antistatic layer 40, for example, an ALPET (registered trademark) sheet obtained by laminating aluminum, such as bonding aluminum foil, on the insulating sheet (film), such as polyethylene terephthalate, a film using an antistatic coating material “COLCOAT” (trade name: made by COLCOAT CO., LTD), PET, polypropylene, and the like are applicable. In addition, in a case where the antistatic layer 40 is simply pressed against and fixed to the sensor substrate 12, there is a case where unnecessary electrical charge is generated at the interface due to the friction between the antistatic layer 40 and the sensor substrate 12 depending on the occurrence of shock or the like. Therefore, it is preferable to bond and fix the antistatic layer 40 to the second surface 14B of the base material 14 of the sensor substrate 12.

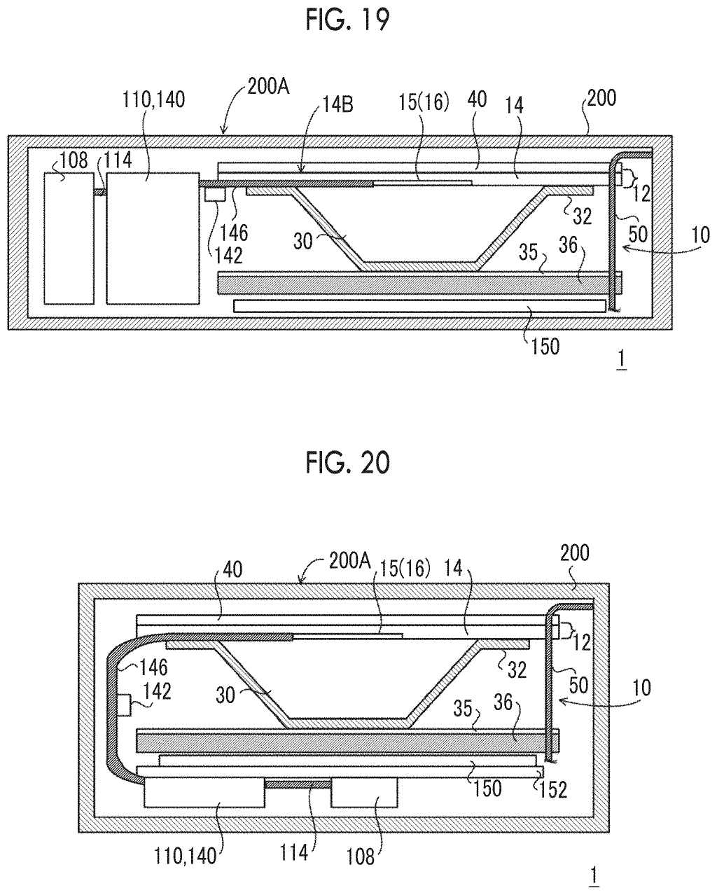

Additionally, an outer peripheral part of the sensor substrate 12 is provided with the wiring line 50 that passes through the base material 14, the adhesive layer 35, the reinforcing substrate 36, and the antistatic layer 40. As an example, as illustrated in FIG. 2, an outer periphery of the sensor substrate 12 of the present embodiment has a rectangular shape, and one corner part of the rectangular shape is provided with a through-hole 52 that also passes through the antistatic layer 40. Additionally, a through-hole 54, which passes through the adhesive layer 35 and the reinforcing substrate 36, is provided at a position that faces the through-hole 52 of the sensor substrate 12 with the laminate 33 interposed therebetween in the adhesive layer 35 and the reinforcing substrate 36. The wiring line 50 is electrically connected to the adhesive layer 35 and the antistatic layer 40. Additionally, the wiring line 50 pass through the through-hole 54 and the through-hole 52, and an end part opposite to the through-hole 54 is connected to a housing 200 (refer to FIGS. 19 and 20) of the radiation detector 10 to be described below in detail.

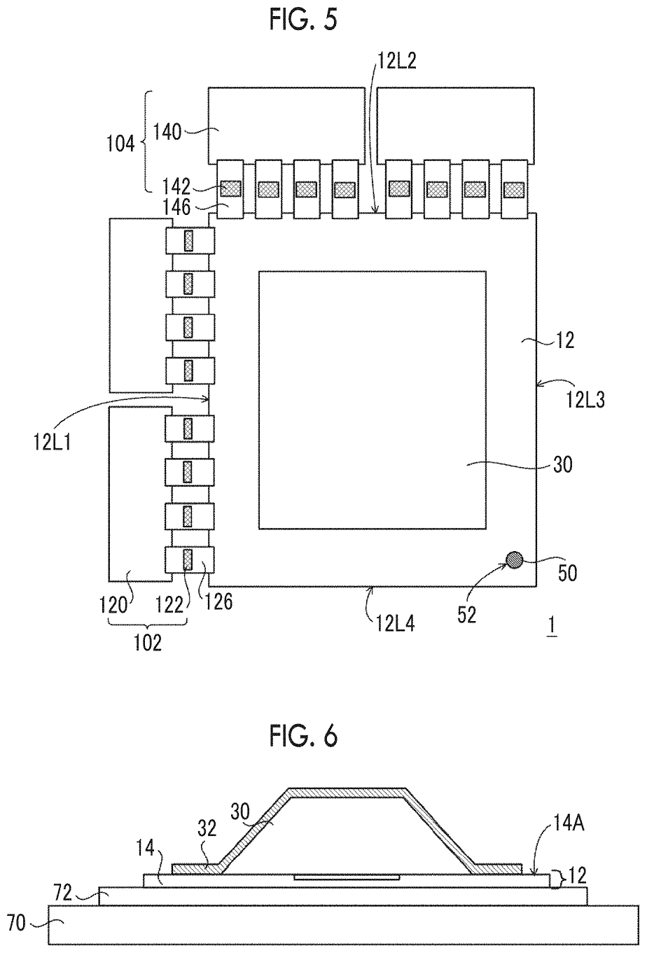

The position of the wiring line 50 (through-hole 52) in the sensor substrate 12 will be described in detail with reference to FIG. 5. FIG. 5 is a plan view of the radiographic imaging apparatus 1 as seen from the side on which the conversion layer 30 is provided. In addition, illustration of the protective layer 32, the adhesive layer 35, and the reinforcing substrate 36 is omitted in FIG. 5.

As illustrated in FIG. 5, a flexible cable 126 (having flexibility) is connected in the vicinity of a side 12L1 of the rectangular sensor substrate 12. A driving substrate 120, and a driving circuit unit 122 mounted on the cable 126 are electrically connected to the above-described scanning wiring lines 26 (refer to FIG. 1) via the cable 126. In the present embodiment, the above-described driving unit 102 (refer to FIG. 1) is realized by circuits and elements that are mounted on the driving substrate 120, and the driving circuit unit 122. The driving circuit unit 122 is an integrated circuit (IC) including circuits excluding the circuits mounted on the driving substrate 120 among various circuits and elements that realize the driving unit 102.

Meanwhile, a flexible cable 146 is connected in the vicinity of a side 12L2 of the sensor substrate 12. A signal processing substrate 140, and a signal processing circuit unit 142 mounted on the cable 146 are electrically connected to the above-described signal wiring lines 24 via the cable 146. In the present embodiment, the above-described signal processing unit 104 (refer to FIG. 1) is realized by circuits and elements that are mounted on the signal processing substrate 140, and the signal processing circuit unit 142. The signal processing circuit unit 142 is an IC including circuits excluding the circuits mounted on the signal processing substrate 140 among various circuits and elements that realize the signal processing unit 104.

As illustrated in FIG. 5, the through-hole 52 is provided at a corner part formed by the side 12L3 and the side 12L4 that are different from the side 12L1 to which the driving unit 102 is connected, and the side 12L2 to which the signal processing unit 104 is connected. In other words, the through-hole 52 is not provided in the vicinity of the side 12L1 to which the driving unit 102 is connected, and in the vicinity of the side 12L2 to which the signal processing unit 104 is connected.

In this way, by providing the through-hole 52 at a position relatively apart from the driving unit 102 and the signal processing unit 104, the position of the wiring line 50 can be made to be a position relatively apart from the driving unit 102 and the signal processing unit 104. Although details will be described below, unnecessary electrical charges, such as electrical charges generated due to causes other than the radiation, in other words, electrical charges that do not contribute to the formation of a radiographic image, flow into the wiring line 50. By providing the wiring line 50 at the position relatively apart from the driving unit 102 and the signal processing unit 104, unnecessary electrical charges flowing through the wiring line 50 causes noise, and an adverse effect on the radiographic image can be suppressed.

In addition, the position of the through-hole 54 (wiring line 50) in the sensor substrate 12 is not limited to the position illustrated in FIG. 5. However, as described above, in order to suppress the adverse effect that the above-described electrical charges flowing through the wiring line 50 has on the radiographic image, it is more preferable that the above position is a position apart from the signal processing unit 104, and it is more preferable that the above position is also a position apart from the driving unit 102.

An example of the method of manufacturing the radiation detector 10 of the present embodiment includes the following method. The reinforcing substrate 36 in which the reinforcing substrate 36 having a desired size adapted to the radiation detector 10 is coated with the adhesive layer 35 is prepared in advance. Meanwhile, as illustrated in FIG. 6, the sensor substrate 12 is formed on a support 70, such as a glass substrate having a thickness larger than that of the base material 14, via a peeling layer 72, for example by a lamination method or the like. Moreover, the conversion layer 30 is directly formed on the sensor substrate 12 by the gaseous phase deposition method as described above, and the protective layer 32 that covers the conversion layer 30 is formed on the first surface 14A of the base material 14 of the sensor substrate 12. Additionally, the cable 126 and the cable 146 (both are not illustrated in FIG. 6) are electrically connected to the sensor substrate 12 as described above.

Then, the reinforcing substrate 36 is bonded to the sensor substrate 12, in which the conversion layer 30 and the protective layer 32 are formed, by the adhesive layer 35. In addition, in a case where the above bonding is performed, the bonding is performed under the atmospheric pressure or under reduced pressure (under vacuum). However, in order to suppress entry of air or the like while being bonded to each other, it is preferable to perform the bonding under reduced pressure.

Thereafter, the sensor substrate 12 is peeled from the support 70 by the peeling layer 72. The peeling method is not particularly limited. For example, in a mechanical peeling method, any of the four sides of the sensor substrate 12 (substrate 14) may be used as a starting point for peeling and the sensor substrate 12 is gradually peeled from the support 70 toward an opposite side from the side to be the starting point. Additionally, for example, in a laser peeling (laser lift-off) method, the sensor substrate 12 may be peeled from the support 70 by radiating a laser beam from a back surface (a surface opposite to the surface on which the sensor substrate 12 is provided) of the support 70 and by decomposing the peeling layer 72 with the laser beam transmitted through the support 70.

After the sensor substrate 12 is peeled from the support 70 in a state where the adhesive layer 35 and the reinforcing substrate 36 are provided, the antistatic layer 40 is bonded to the second surface 14B of the base material 14 of the sensor substrate 12.

Thereafter, the through-hole 52 passing through the base material 14 of the antistatic layer 40 and the sensor substrate 12, and the through-hole 54 passing through the adhesive layer 35 and the reinforcing substrate 36 are formed, and the wiring line 50 is passed through the through-hole 52 and the through-hole 54. Then, the adhesive layer 35 and the wiring line 50 are electrically connected to each other, and the antistatic layer 40 and the wiring line 50 are electrically connected to each other.

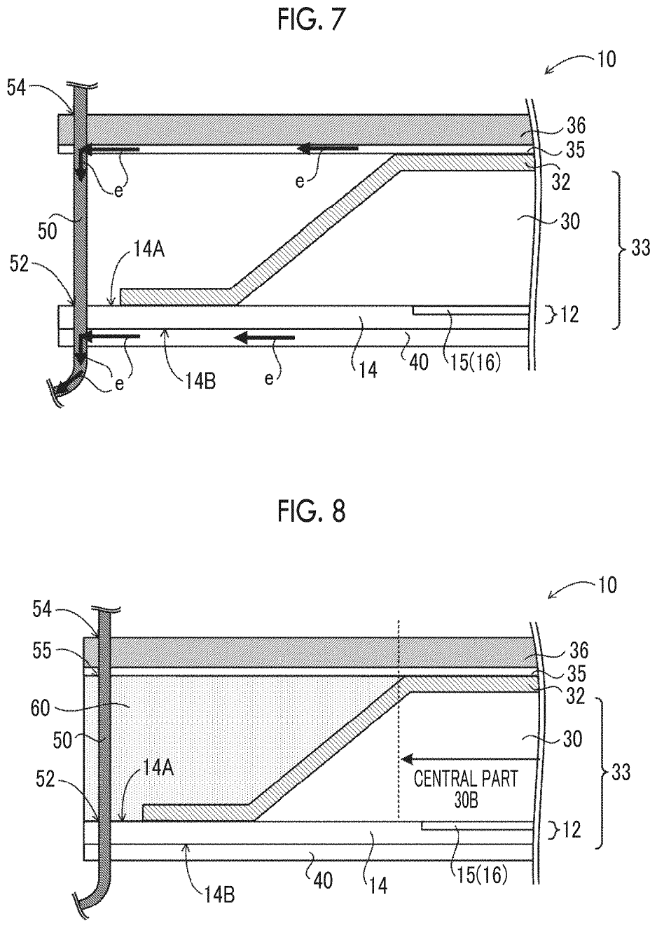

Next, the operation of the radiation detector 10 of the present embodiment will be described with reference to FIG. 7. Since the base material 14 of the sensor substrate 12 has flexibility, the radiation detector 10 tends to generate electrical charges due to friction and the like in a case where the base material 14 (sensor substrate 12) is deflected. In other words, the radiation detector 10 of the present embodiment tends to generate electrical charges due to causes other than the radiation. The electrical charges generated in this way stay in the adhesive layer 35 and the antistatic layer 40. The electrical charges that stay in each of the adhesive layer 35 and the antistatic layer 40 move as indicated by arrows e of FIG. 7, and are discharged to the outside of the radiation detector 10 by the wiring line 50.

In the radiation detector 10 of the present embodiment, the wiring line 50 passes through the through-hole 52 of the sensor substrate 12. In this way, in the radiation detector 10 of the present embodiment, the wiring line 50 passes through the through-hole 52 provided in the base material 14 of the sensor substrate 12. Therefore, even in a case where the base material 14 is deflected, the wiring line 50 is not easily peeled from the antistatic layer 40, and the electrical connection between the wiring line 50 and the antistatic layer 40 is not easily cut.

Moreover, in the radiation detector 10 of the present embodiment, the wiring line 50 passes through the through-hole 54 and is electrically connected to the adhesive layer 35. Therefore, even in a case where the base material 14 (sensor substrate 12) is deflected, the wiring line 50 is not easily peeled from the adhesive layer 35, and the electrical connection between the wiring line 50 and the adhesive layer 35 is not easily cut.

In this way, according to the radiation detector 10 of the present embodiment, in the radiation detector 10 comprising the sensor substrate 12 using the flexible base material 14, the electrical charges generated due to causes other than the radiation can be effectively discharged to the outside of the radiation detector 10.

Additionally, in the radiation detector 10 of the present embodiment, the wiring line 50 passes through the through-hole 52 provided within the sensor substrate 12 and the through-hole 54 provided within the adhesive layer 35 and the reinforcing substrate 36. Therefore, compared to a case where a wiring line passes through side surfaces (outsides, such as the sides 12L3 and 12L4 of the sensor substrate 12) of the radiation detector 10 (sensor substrate 12), a space where the wiring line 50 is provided can be saved. Therefore, according to the radiation detector 10 of the present embodiment, the radiographic imaging apparatus 1 can be downsized.

Additionally, according to the radiation detector 10 of the present embodiment, the reinforcing substrate 36 is provided on the surface of the laminate 33 on the conversion layer 30 side. Therefore, the reinforcing substrate 36 can make it difficult to deflect the base material 14 (sensor substrate 12). Since it is difficult for the sensor substrate 12 to be deflected, the electrical connection between the wiring line 50, and the adhesive layer 35 and the antistatic layer 40 can be made it difficult to cut. Additionally, according to the radiation detector 10 of the present embodiment, it is possible to suppress that the conversion layer 30 is broken as the sensor substrate 12 is deflected. Therefore, the quality of a radiographic image can be improved.

Additionally, in the radiation detector 10 of the present embodiment, the wiring line 50 does not pass through the protective layer 32. In a case where a through-hole is provided in the protective layer 32, there is a concern that moisture resistance to the conversion layer 30 decreases due to the through-hole. For that reason, as in the radiation detector 10 of the present embodiment, it is preferable to adopt a form in which the wiring line 50 does not pass through the protective layer 32.

### Second Embodiment

Next, a second embodiment will be described. FIG. 8 is a cross-sectional view of an example of the radiation detector 10 of the present embodiment.

As illustrated in FIG. 8, in the radiation detector 10 of the present embodiment, a filler material 60 is filled between the first surface 14A of the base material 14 of the sensor substrate 12 on which the conversion layer 30 is formed, and the adhesive layer 35 and the reinforcing substrate 36. That is, the radiation detector 10 of the present embodiment is different from the radiation detector 10 (refer to FIG. 3) of the first embodiment in that a space opening between the sensor substrate 12 on which the conversion layer 30 is formed, and the adhesive layer 35 and the reinforcing substrate 36 is filled with the filler material 60.

The material of the filler material 60 is not particularly limited, and sealants of general semiconductor materials, can be used. Additionally, the method of providing the filler material 60 is not particularly limited. For example, the filler material 60 may be provided by injecting the filler material 60 having fluidity into a space (gap) between the sensor substrate 12 on which the conversion layer 30 covered with the protective layer 32 is formed, and the adhesive layer 35 and the reinforcing substrate 36, and by hardening the filler material 60. Additionally, for example, the filler material 60 may be provided by placing the filler material 60 having fluidity in a spot where the filler material 60 is to be filled in a state where the conversion layer 30 and the protective layer 32 are formed on the sensor substrate 12, and by bonding the reinforcing substrate 36 onto the conversion layer 30 and the filler material 60 covered with the protective layer 32 by the adhesive layer 35.

The filler material 60 is provided with a through-hole 55 connected to the through-hole 52 and the through-hole 54. The wiring line 50 is provided in a state where the wiring line 50 passes through the through-hole 54, the through-hole 55, and the through-hole 52, and is electrically connected to the adhesive layer 35 and the antistatic layer 40.

In this way, in the radiation detector 10 of the present embodiment, the filler material 60 is filled between the sensor substrate 12, and the adhesive layer 35 and the reinforcing substrate 36, and the wiring line 50 passes through the through-hole 54, the through-hole 55, and the through-hole 52. For that reason, according to the radiation detector 10 of the present embodiment, even in a case where the base material 14 (sensor substrate 12) is deflected, the wiring line 50 is not easily peeled from the adhesive layer 35 and the antistatic layer 40, and the electrical connection between the wiring line 50, and the adhesive layer 35, and the antistatic layer 40 is not easily cut.

Therefore, also in the radiation detector 10 of the present embodiment, the electrical charges generated due to causes other than the radiation can be effectively discharged to the outside of the radiation detector 10 in the radiation detector 10 comprising the sensor substrate 12 using the flexible base material 14.

Additionally, according to the radiation detector 10 of the present embodiment, it is possible to suppress that the sensor substrate 12 is greatly deflected by the filler material 60 and the reinforcing substrate 36. Therefore, the electrical connection between the wiring line 50, and the adhesive layer 35 and the antistatic layer 40 can be made it difficult to cut. Additionally, according to the radiation detector 10 of the present embodiment, it is possible to suppress that the conversion layer 30 is broken as the sensor substrate 12 is deflected. Therefore, the quality of a radiographic image can be further improved.

Additionally, in the radiation detector 10 of the present embodiment, the reinforcing substrate 36 previously protruding ahead from the central part 30B of the conversion layer 30 (to the end part side of the sensor substrate 12) is supported by the filler material 60. For that reason, according to the radiation detector 10 of the present embodiment, the reinforcing substrate 36 is stably provided, and is not easily peeled from the sensor substrate 12 and the conversion layer 30. Additionally, according to the radiation detector 10 of the present embodiment, the conversion layer 30 is fixed to the sensor substrate 12 by the reinforcing substrate 36 and the filler material 60. Therefore, the conversion layer 30 is not easily peeled from the sensor substrate 12. Therefore, according to the radiation detector 10 of the present embodiment, the quality of a radiographic image can be further improved.

In addition, a form in which the filler material 60 is filled between the conversion layer 30 the sensor substrate 12 on which is formed, and the adhesive layer 35 and the reinforcing substrate 36 is illustrated in the example illustrated in FIG. 8. However, the invention is not limited to the form illustrated in FIG. 8. For example, a gap (a region where the filler material 60 is not filled) may be present in a portion between the sensor substrate 12 on that the conversion layer 30 is formed, and the adhesive layer 35 and the reinforcing substrate 36.

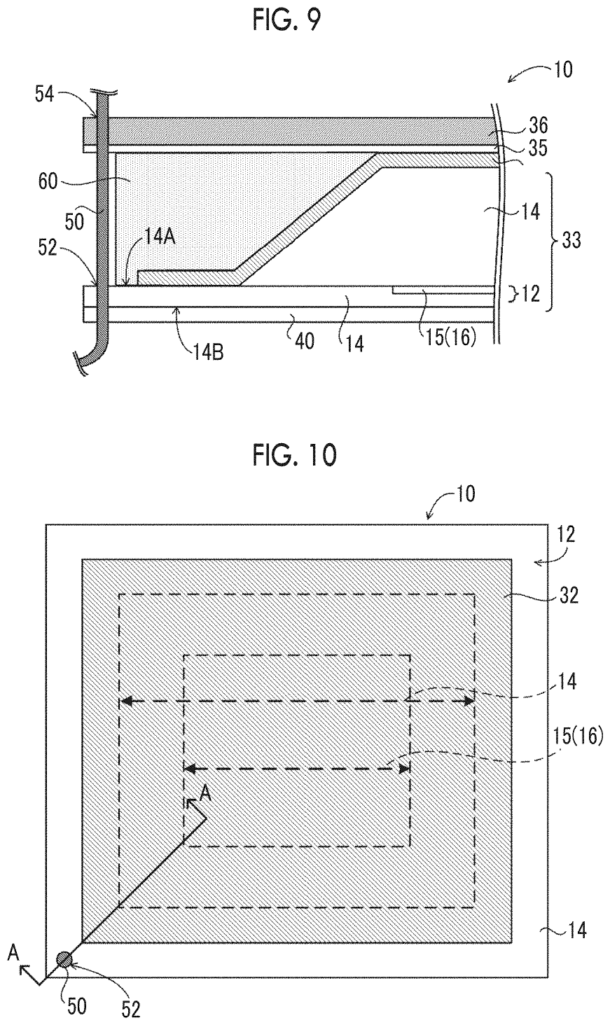

Additionally, for example, as in the radiation detector 10 illustrated in FIG. 9, a form in which a region through which the wiring line 50 passes, in other words, a region that covers the through-hole 52 and the through-hole 54 is not filled with the filler material 60 may be adopted. In the form illustrated in FIG. 9, the wiring line 50 does not pass through the inside of the filler material 60. However, the sensor substrate 12 is not easily deflected by the filler material 60. Therefore, also in the radiation detector 10 illustrated in FIG. 9, the wiring line 50 is not easily peeled from the adhesive layer 35 and the antistatic layer 40, and the electrical connection between the wiring line 50, and the adhesive layer 35 and the antistatic layer 40 is not easily cut.

### Third Embodiment

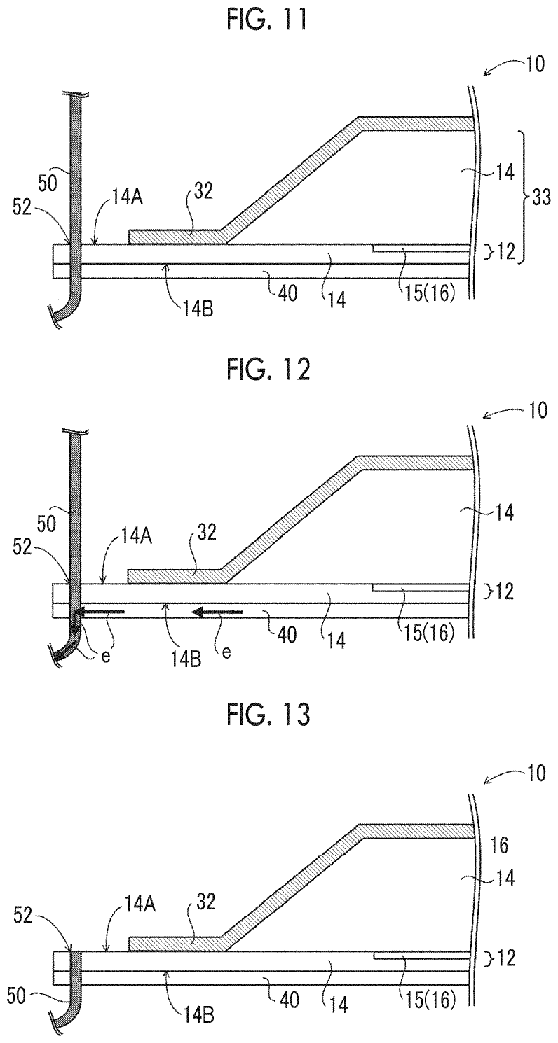

Next, a third embodiment will be described. FIG. 10 is a plan view of a radiation detector 10 of the present embodiment as seen from the side on which the conversion layer 30 is formed. Additionally, FIG. 11 is a cross-sectional view taken along line A-A of the radiation detector 10 in FIG. 10.

As illustrated in FIGS. 10 and 11, in the radiation detector 10 of the present embodiment is different from the radiation detector 10 (refer to FIGS. 2 and 3) of the first embodiment in that the adhesive layer 35 and the reinforcing substrate 36 are not provided.

As illustrated in FIG. 11, the wiring line 50 in the radiation detector 10 of the present embodiment passes through the through-hole 52 provided in the sensor substrate 12, and is electrically connected to the antistatic layer 40.

Also in the radiation detector 10 of the present embodiment, as illustrated in FIG. 12, the electrical charges, which are generated due to causes other than the radiation and stay in the antistatic layer 40, move as indicated by arrow e, and are discharged to the outside of the radiation detector 10 by the wiring line 50.

Also the radiation detector 10 of the present embodiment, the wiring line 50 passes through the through-hole 52 provided in the base material 14 of the sensor substrate 12. Therefore, even in a case where the base material 14 is deflected, the wiring line 50 is not easily peeled from the antistatic layer 40, and the electrical connection between the wiring line 50 and the antistatic layer 40 is not easily cut.

Therefore, according to the radiation detector 10 of the present embodiment, in the radiation detector 10 comprising the sensor substrate 12 using the flexible base material 14, the electrical charges generated due to causes other than the radiation can be effectively discharged to the outside of the radiation detector 10.

In addition, in a case where the adhesive layer 35 and the reinforcing substrate 36 are not provided, a distal end of the wiring line 50 passing through the through-hole 52 may not protrude ahead from the first surface 14A of the base material 14 as in a radiation detector 10 illustrated in FIG. 13.

As described above, the radiation detectors 10 of the above respective embodiments comprise the sensor substrate 12 having the pixel region 15 where the plurality of pixels 16 that accumulate the electrical charges generated depending on the light converted from the radiation are formed on the first surface 14A of the flexible and resinous base material 14, the conversion layer 30 that is provided in a partial region, including the pixel region 15, of the first surface 14A of the base material 14 and converts the radiation into light, the electrical charge discharge layer that is at least one of the adhesive layer 35 provided on the surface, on the conversion layer 30 side, in the laminate 33 in which the sensor substrate 12 and the conversion layer 30 are laminated, or the antistatic layer 40 provided on the second surface 14B opposite to the first surface 14A of the base material 14, and a wiring line 50 that is electrically connected to the electrical charge discharge layer, the base material 14 has the through-hole 52 provided in the region corresponding to the region other than the partial region, and the wiring line 50 passes through the through-hole 52.

According to the radiation detectors 10 of the above respective embodiments, the wiring line 50 passes through the through-hole 52 provided in the base material 14. Therefore, even in a case where the base material 14 (sensor substrate 12) is deflected, the electrical connection between the wiring line 50 and the antistatic layer 40 can be made it difficult to cut. According to the radiation detectors 10 of the above respective embodiments, the unnecessary electrical charges, which do not contribute to a radiographic image, such as the electrical charges that stay in the antistatic layer 40, can be effectively and rapidly discharged. Therefore, the quality of a radiographic image to be generated can be improved.

Therefore, according to the radiation detectors 10 of the above respective embodiments, even in a case where the flexible base material 14 is used for the sensor substrate 12, the electrical charges that cause unevenness in a radiographic image can be effectively discharged to the outside, compared to a case where the wiring line 50 for connecting the electrical charge discharge layer to the ground passes through outsides, such as the sides 12L3 and 12L4 of the sensor substrate 12.

Additionally, according to the radiation detectors 10 of the above respective embodiments, the wiring line 50 passes through the through-hole 52 provided in the base material 14. Therefore, according to the radiation detector 10 of the present embodiment, in a case where the wiring line 50 passes through the outside of the radiation detector 10, for example, as compared to a case where the wiring line 50 passes through the side surface of the radiation detector 10 (sensor substrate 12), the radiographic imaging apparatus 1 can be downsized.

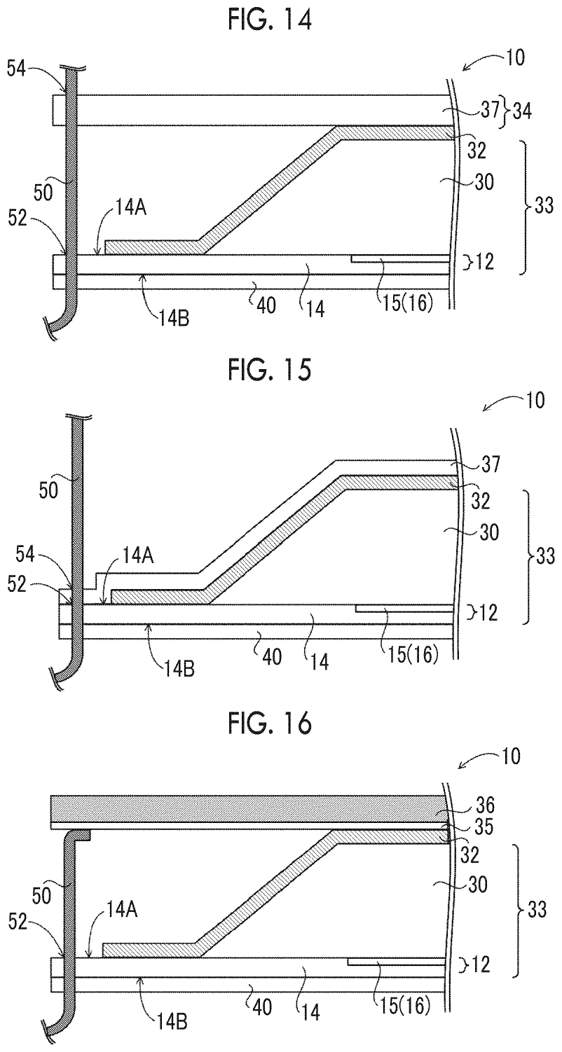

In addition, a form in which a layer having the function of the electrical charge discharge layer of the present disclosure is provided on the surface of the laminate 33 on the conversion layer 30 side in the radiation detector 10 is not limited to the form in which the adhesive layer 35 is provided, as described in the above first and second embodiments. For example, as in an example illustrated in FIG. 14, a form including the conductive resin film 37 that functions as the conductive layer of the present disclosure may be adopted instead of the above-described adhesive layer 35 and reinforcing substrate 36 (refer to FIG. 3 and the like). Examples of the conductive resin film 37 include a film in which a conductive substance is mixed with a thermoplastic resin. The wiring line 50 passes through the through-hole 54 and through-hole 52 that are provided in the conductive resin film 37, and is electrically connected to the conductive resin film 37 and the antistatic layer 40. In the conductive resin film 37, any one of a higher stiffness than the base material 14 and a larger thickness than the base material 14 may be specified. In this case, the base material 14 can be made it difficult to deflect similarly to the above-described reinforcing substrate 36.

Additionally, for example, as in an example illustrated in FIG. 15, the conductive resin film 37 having the function of the electrical charge discharge layer of the present disclosure may be provided on the entire first surface 14A of the base material 14 on which the conversion layer 30 covered with the protective layer 32 is provided, in a state of being in contact with the protective layer 32 and the first surface 14A. In the example illustrated in FIG. 15, a state where the conductive resin film 37 is brought in close contact with an outer edge the first surface 14A, and the protective layer 32, is illustrated. The wiring line 50 passes through the through-hole 54 provided in the conductive resin film 37, and the through-hole 52 provided in the base material 14, and is electrically connected to the conductive resin film 37 and the antistatic layer 40. Therefore, also in the radiation detectors 10 illustrated in FIGS. 14 and 15, the same effects as those of the radiation detector 10 of the first embodiment are obtained.

Additionally, for example, as the form in which the adhesive layer 35 is provided, the methods of connecting the adhesive layer 35 and the wiring line 50 to each other are not limited to the above-described forms. For example, a form in which an end part of the wiring line 50 is electrically connected to the surface of the adhesive layer 35 that faces the sensor substrate 12 may be adopted as in an example illustrated in FIG. 16, instead of passing the wiring line 50 through the through-hole 54 (refer to FIG. 3 and the like) provided in the adhesive layer 35 and the reinforcing substrate 36. The reinforcing substrate 36 is not easily deflected compared to the base material 14. Therefore, even in a case where the wiring line 50 is provided without being passed through a through-hole as in the radiation detector 10 of an example illustrated in FIG. 16, the adhesive layer 35 and the wiring line 50 is not easily electrically cut compared to the connection between the base material 14 and the antistatic layer 40. For that reason, as illustrated in FIG. 16, it is not necessary to provide a through-hole in the adhesive layer 35 and the reinforcing substrate 36.

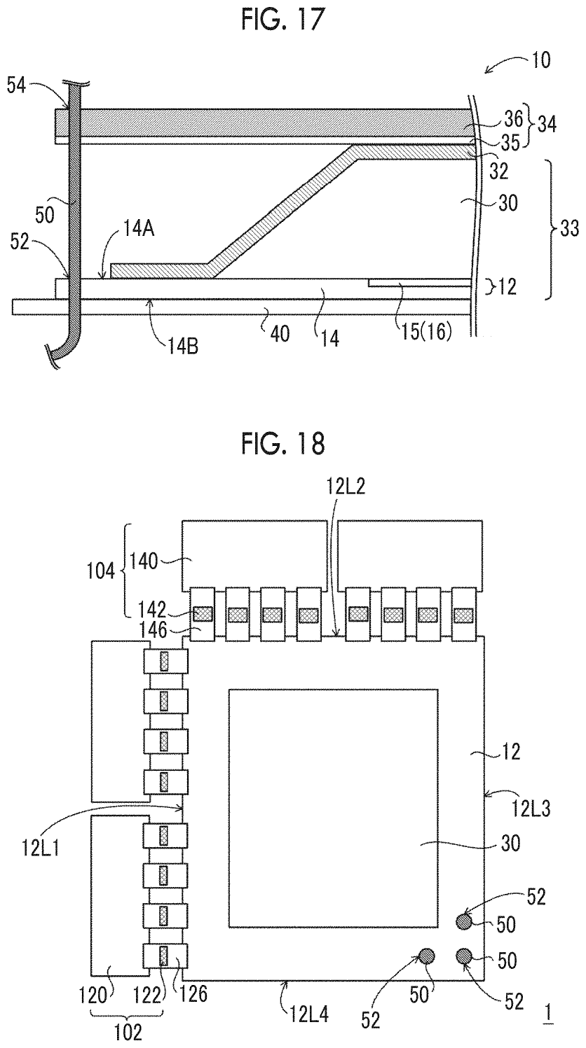

Additionally, a form in which the radiation detector 10 is provided with the antistatic layer 40 is also not limited to the forms described in the above respective embodiments. For example, as in the radiation detector 10 of the example illustrated in FIG. 17, a form in which the size of the antistatic layer 40 is made larger than the base material 14 (sensor substrate 12) and the region of an outer edge part of the antistatic layer 40 protrudes farther than an outer edge part of the sensor substrate 12 may be adopted. In the radiation detector 10 of the form illustrated in FIG. 17, the electrical charges that stay in the antistatic layer 40 can be further discharged by connecting the region of the outer edge part, from which the antistatic layer 40 protrudes, to a part that supplies constant potential, such as the housing 200 (refer to FIGS. 19 and 20), that is, taking the so-called ground. Additionally, in the form illustrated in FIG. 17, conversely, the size of the antistatic layer 40 may be made smaller than the base material 14 (sensor substrate 12).

Additionally, positions where the wiring line 50 (through-hole 52) is provided, and the number of wiring lines 50 are also not limited to the forms described in the above respective embodiments. As an example, a plan view of the radiographic imaging apparatus 1 comprising the radiation detector 10 provided with three wiring lines 50 (through-holes 52) is illustrated in FIG. 18. By providing two or more wiring lines 50 (through-holes 54) as in the radiation detector 10 illustrated in FIG. 18, the electrical charges that stay in the antistatic layer 40 can be made it easier to discharge.

Additionally, the size of the pixel region 15 is not limited to the above respective embodiments. For example, in the above respective embodiments, a form in which the size of the pixel region 15 is smaller than the size of the central part 30B of the conversion layer 30 and the outer periphery of the pixel region 15 is within the central part 30B has been described. However, the invention is not limited to the above forms, a form in which the size of the pixel region 15 is larger than the size of the central part 30B of the conversion layer 30 and the outer periphery of the pixel region 15 reaches the peripheral edge part 30C of the conversion layer 30 may be adopted. In this case, the size of the entire radiation detector 10 can be made small. In addition, the quantity of light converted from the radiation in the conversion layer 30 tends to decrease as the thickness of the conversion layer 30 decreases. Therefore, similarly to the radiation detectors 10 of the above respective embodiments, the thickness of the conversion layer 30 on the pixel region 15 is more substantially uniform in the form in which the outer periphery of the pixel region 15 within the central part 30B. Therefore, the sensitivity characteristics of the pixel region 15 are improved.

Additionally, in the above respective embodiments, as illustrated in FIG. 1, an aspect in which the pixels 16 are two-dimensionally arranged in a matrix has been described. However, the invention is not limited, and the pixels 16 may be one-dimensionally arranged or may be arranged in a honeycomb arrangement. Additionally, the shape of the pixels is also not limited, and may be a rectangular shape, or may be a polygonal shape, such as a hexagonal shape. Moreover, the shape of the pixel region 15 is also not limited.

Additionally, the shape or the like of the conversion layer 30 is not limited to the above respective embodiments. In the above respective embodiments, an aspect in which the shape of the conversion layer 30 is a rectangular shape similarly to the shape of the pixel region 15 has been described. However, the shape of the conversion layer 30 may not be the same shape as that of the pixel region 15. Additionally, the shapes of the pixel region 15 may not be a rectangular shape and may be, for example, other polygonal shapes or a circular shape.

In addition, the radiation detectors 10 of the above respective embodiments may be applied to an irradiation side sampling (ISS) type radiographic imaging apparatus in which radiation is radiated from the sensor substrate 12 side, or may be applied to a penetration side sampling (PSS) type radiographic imaging apparatus in which radiation is radiated from the conversion layer 30 side.

A cross-sectional view of an example in a state where the radiation detector 10 of the first embodiment is applied to an irradiation side sampling type radiographic imaging apparatus 1 is illustrated in FIG. 19.

As illustrated in FIG. 19, the radiation detector 10, the power source unit 108, the control substrate 110, and the signal processing substrate 140 are provided side by side in a direction intersecting an incidence direction of radiation within the housing 200. The radiation detector 10 is provided in a state where the second surface 14B of the base material 14 faces an imaging surface 200A side of the housing 200 that is irradiated with radiation transmitted through a subject.

Each of the driving substrate 120 and the signal processing substrate 140 is electrically connected to the control substrate 110 by a wiring line (not illustrated). Additionally, the control substrate 110 is connected to the power source unit 108, which supplies electrical power to the image memory 106, the control unit 100, and the like (refer to FIG. 1 for all) that are formed in the control substrate 110, by a power source line 114.

A sheet 150 is further provided on a side from which the radiation transmitted through the radiation detector 10 is emitted, within the housing 200 of the radiographic imaging apparatus 1 illustrated in FIG. 19. The sheet 150 is, for example, a copper sheet. The copper sheet does not easily generate secondary radiation due to incident radiation, and therefore, has a function of preventing scattering to the rear side, that is, the conversion layer 30 side. In addition, the sheet 150 covers at least an entire surface of the conversion layer 30 from which radiation is emitted, and it is preferable that the sheet 150 covers the entire conversion layer 30.

In a radiographic imaging apparatus 1 illustrated in FIG. 19, the wiring line 50 electrically connected to the adhesive layer 35 and the antistatic layer 40 of the radiation detector 10 and the housing 200 are electrically connected to each other. In other words, the adhesive layer 35 and the antistatic layer 40 are connected to the housing 200 serving as a frame ground by the wiring line 50. For that reason, in the radiation detector 10 illustrated in FIG. 19, the electrical charges that stay in the adhesive layer 35 and the antistatic layer 40 are effectively and rapidly discharged to the housing 200 via the wiring line 50.

In addition, although FIG. 19 illustrates a form in which the power source unit 108, the control substrate 110, and the signal processing substrate 140 are provided on one side of the radiation detector 10, specifically, on one side of the rectangular pixel region 15, a position where the power source unit 108, the control substrate 110, and the signal processing substrate 140 are provided is not limited to the form illustrated in FIG. 19. For example, the power source unit 108 and the control substrate 110 may be provided so as to be respectively decentralized onto two facing sides of the pixel array 31, or may be provided so as to be respectively decentralized onto two adjacent sides.

Additionally, a cross-sectional view of another example in a state where the radiation detector 10 of the first embodiment is applied to the irradiation side sampling type radiographic imaging apparatus 1 is illustrated in FIG. 20.

As illustrated in FIG. 20, the power source unit 108, the control substrate 110, and the signal processing substrate 140 are provided side by side in the direction intersecting the incidence direction of radiation within the housing 200.

Additionally, in a radiographic imaging apparatus 1 illustrated in FIG. 20, a base 152 that supports the radiation detector 10 and the control substrate 110 is provided between the control substrate 110, the signal processing substrate 140, and the power source unit 108, and the sheet 150. For example, carbon or the like is used for the base 152.

Also in a radiographic imaging apparatus 1 illustrated in FIG. 20, similarly to the radiation detector 10 illustrated in FIG. 19, the adhesive layer 35 and the antistatic layer 40 are connected to the housing 200 serving as the frame ground by the wiring line 50. For that reason, also in the radiation detector 10 illustrated in FIG. 20, the electrical charges that stay in the adhesive layer 35 and the antistatic layer 40 are effectively and rapidly discharged to the housing 200 via the wiring line 50.

In addition, the configurations, manufacturing methods, and the like of the radiation detectors 10, and the like that are described in the above respective embodiments are merely examples, and can be modified in accordance with situations without departing from the scope of the invention.

What is claimed is:

1. A radiation detector comprising:
a substrate having a pixel region where a plurality of pixels that accumulate electrical charges generated depending on light converted from radiation are formed on a first surface of a flexible and resinous base material;
a conversion layer that is provided in a partial region, including the pixel region, of the first surface of the base material and converts the radiation into the light;
an electrical charge discharge layer that is provided on at least one surface of a surface, on the conversion layer side, in a laminate in which the substrate and the conversion layer are laminated, or a second surface opposite to the first surface of the base material; and
a wiring line that is electrically connected to the electrical charge discharge layer,
wherein the base material has a through-hole provided in a region corresponding to a region other than the partial region, and the wiring line passes through the through-hole.

2. The radiation detector according to claim 1,
wherein the electrical charge discharge layer is at least one of an antistatic layer or a conductive layer.

3. The radiation detector according to claim 1,
wherein the electrical charge discharge layer is provided on the surface of the laminate on the conversion layer side, and has a higher stiffness than the base material.

4. The radiation detector according to claim 1,
wherein the electrical charge discharge layer is provided on the surface of the laminate on the conversion layer side, and is thicker than the base material.

5. The radiation detector according to claim 1,
wherein the electrical charge discharge layer is an adhesive layer that is provided on the surface of the laminate on the conversion layer side, is electrically connected to the wiring line, and has conductivity, and
wherein the radiation detector further comprises a reinforcing substrate bonded to the laminate by the adhesive layer.

6. The radiation detector according to claim 5,
wherein the reinforcing substrate has a higher stiffness than the base material.

7. The radiation detector according to claim 5,
wherein the reinforcing substrate is provided on the surface of the laminate on the conversion layer side and is thicker than the base material.

8. The radiation detector according to claim 1,
wherein the wiring line passes through the electrical charge discharge layer.

9. The radiation detector according to claim 1, further comprising:
a protective layer that is provided on the first surface of the base material and covers the conversion layer,
wherein the through-hole provided in the base material is provided outside a region where the protective layer is provided.

10. The radiation detector according to claim 1,
wherein the base material is provided with a plurality of the through-holes.

11. A radiographic imaging apparatus comprising:
the radiation detector according to claim 1;
a driving unit that is electrically connected to one side of the substrate and causes electrical charges to be read from the plurality of pixels depending on a control signal; and
a signal processing unit that is electrically connected to a side different from the one side of the substrate, receives electrical signals according to the electrical charges read from the plurality of pixels, and generates image data according to the input electrical signals.

12. The radiographic imaging apparatus according to claim 11,
wherein the through-hole provided in the base material is provided at a side of the base material different from the sides to which the driving unit and the signal processing unit are connected.

13. The radiographic imaging apparatus according to claim 11, further comprising:
a housing that houses the radiation detector, the driving unit, and the signal processing unit,
wherein the wiring line is electrically connected to the housing.
